(19) United States
(12) Patent Application Publication
(10) Pub. No.: US 2015/0277490 A1
(43) Pub. Date: Oct. 1, 2015

(54) ELECTRONIC DEVICE

(71) Applicants: Kenneth Jasinski, South San Francisco, CA (US); Sameer Sharma, Santa Clara, CA (US); Daniel Clifton, San Francisco, CA (US); Yoshikazu Hoshino, San Francisco, CA (US); Gadi Amit, San Mateo, CA (US); Chadwick Harber, San Francisco, CA (US)

(72) Inventors: Kenneth Jasinski, South San Francisco, CA (US); Sameer Sharma, Santa Clara, CA (US); Daniel Clifton, San Francisco, CA (US); Yoshikazu Hoshino, San Francisco, CA (US); Gadi Amit, San Mateo, CA (US); Chadwick Harber, San Francisco, CA (US)

(21) Appl. No.: 14/229,421

(22) Filed: Mar. 28, 2014

(51) Int. Cl. G06F 1/16; H05K 5/02; H05K 5/00

(52) U.S. Cl. CPC G06F 1/1616; H05K 5/0004; H05K 5/02; H05K 5/0086; H05K 5/0226

(57) ABSTRACT

In one example a chassis for an electronic device comprises a first housing and a second housing, the second housing coupled to the first housing such that the second housing is rotatable about an axis that extends diagonally through the first housing and the second housing. Other examples may be described.

### BACKGROUND

The subject matter described herein relates generally to the field of electronic devices and more particularly to portable electronic devices.

Many electronic devices utilize a “clamshell” chassis. By way of example, many laptop computers and mobile electronic devices utilize a clamshell chassis in which a keyboard is disposed on a first housing and a display is disposed on a second housing coupled to the first housing by a hinge. Alternatively, a “clamshell” can consist of displays, one on a first housing that can also be utilized as a touch keyboard and one display on a second housing coupled to the first housing by a hinge.

The advent of tablet computers has driven a market for laptop devices that are convertible between a traditional notebook and a tablet configuration. Accordingly chasses which enable an electronic device to convert between configurations may find utility.

### BRIEF DESCRIPTION OF THE DRAWINGS

The detailed description references the accompanying figures.

FIG. 1 is a schematic illustration of an exemplary electronic device which in accordance with some examples.

FIG. 2A is a side view of an exemplary electronic device in accordance with some examples.

FIG. 2B is a plan view of an exemplary electronic device in accordance with some examples.

FIGS. 2C-2D are schematic illustrations of an exemplary electronic device in accordance with some examples.

FIG. 3 is a schematic illustration of an exemplary hinge assembly in accordance with some examples.

FIGS. 4A-4B are schematic illustrations of an exemplary electronic device in accordance with some examples.

FIG. 5 is a flowchart illustrating operations implemented in a control logic of an electronic device in accordance with some examples.

FIGS. 6-10 are schematic illustrations of electronic devices which may be modified to include a hinge assembly in accordance with some examples.

### DETAILED DESCRIPTION

In the following description, numerous specific details are set forth to provide a thorough understanding of various examples. However, it will be understood by those skilled in the art that the various examples may be practiced without the specific details. In other instances, well-known methods, procedures, components, and circuits have not been illustrated or described in detail so as not to obscure the particular examples.

Electronic devices such as, e.g., tablet computing devices typically provide a lackluster keyboard interface. Touch-screen keyboards have proven difficult to use and keyboards which are connectable to the electronic device present an inconvenience.

Described herein are examples of an electronic device which is convertible between a tablet configuration and a notebook configuration. In some examples the comprises a first housing and a second housing coupled to the first housing such that the second housing is rotatable about an axis that extends diagonally through portions of the first housing and the second housing. When the electronic device is in a tablet configuration the second housing is substantially parallel with and adjacent to the first housing such that the first housing and the second housing present substantially coplanar surfaces which may incorporate displays.

Rotating the second housing about the axis repositions the respective first housing and second housing such that the electronic device is in a configuration that is typical of notebook computing devices. The first housing may comprise a keyboard and in this configuration the keyboard is presented for user interaction, while the second housing presents a display.

The electronic device may comprise logic to detect whether the electronic device is in a tablet configuration or a notebook configuration and to adjust one or more operating parameters in accordance with the configuration. For example, if the logic detects that the electronic device is in a table configuration then the logic may activate displays on both the first housing and the second housing. Alternatively, if the logic detects that device is switched to a notebook configuration then the logic may deactivate the display on the first housing and activate a keyboard on the first housing.

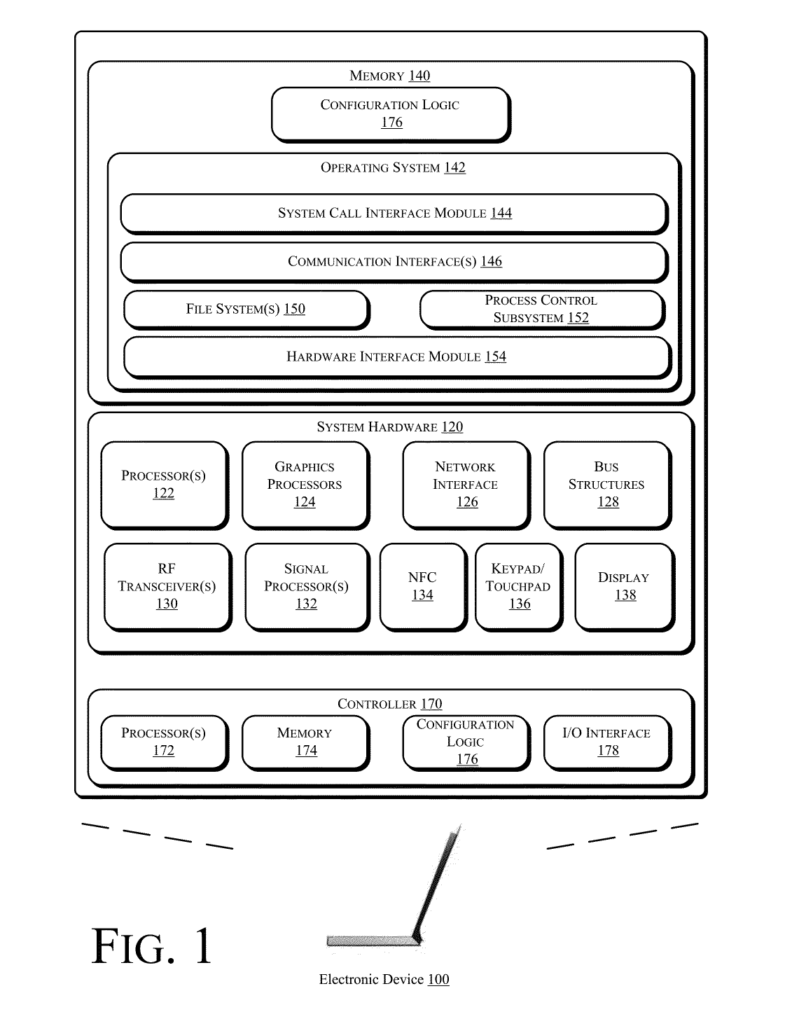

A detailed description of examples of an electronic device will be provided below with reference to FIGS. 1-10.

Referring first to FIG. 1, electronic device 100 may be embodied as a conventional portable electronic device. In various examples, electronic device 100 may include or be coupled to one or more accompanying input/output devices including a display, one or more speakers, a keyboard, one or more other I/O device(s), a mouse, a camera, or the like. Other exemplary I/O device(s) may include a touch screen, a voice-activated input device, a track ball, a geolocation device, an accelerometer/gyroscope, biometric feature input devices, and any other device that allows the electronic device 100 to receive input from a user.

The electronic device 100 includes system hardware 120 and memory 140, which may be implemented as random access memory and/or read-only memory. A file store may be communicatively coupled to electronic device 100. The file store may be internal to electronic device 100 such as, e.g., eMMC, SSD, one or more hard drives, or other types of storage devices. The file store may also be external to electronic device 100 such as, e.g., one or more external hard drives, network attached storage, or a separate storage network.

System hardware 120 may include one or more processors 122, graphics processors 124, network interfaces 126, and bus structures 128. In one example, processor 122 may be embodied as an Intel® Atom™ processors, Intel® Atom™ based System-on-a-Chip (SOC) or Intel® Core2 Duo® or i3/i5/i7 series processor available from Intel Corporation, Santa Clara, Calif., USA. As used herein, the term “processor” means any type of computational element, such as but not limited to, a microprocessor, a microcontroller, a complex instruction set computing (CISC) microprocessor, a reduced instruction set (RISC) microprocessor, a very long instruction word (VLIW) microprocessor, or any other type of processor or processing circuit.

Graphics processor(s) 124 may function as adjunct processor that manages graphics and/or video operations. Graphics processor(s) 124 may be integrated onto the motherboard of electronic device 100 or may be coupled via an expansion slot on the motherboard or may be located on the same die or same package as the Processing Unit.

In one example, network interface 126 could be a wired interface such as an Ethernet interface (see, e.g., Institute of Electrical and Electronics Engineers/IEEE 802.3-2002) or a wireless interface such as an IEEE 802.11a, b or g-compliant interface (see, e.g., IEEE Standard for IT-Telecommunications and information exchange between systems LAN/MAN-Part II: Wireless LAN Medium Access Control (MAC) and Physical Layer (PHY) specifications Amendment 4: Further Higher Data Rate Extension in the 2.4 GHz Band, 802.11G-2003). Another example of a wireless interface would be a general packet radio service (GPRS) interface (see, e.g., Guidelines on GPRS Handset Requirements, Global System for Mobile Communications/GSM Association, Ver. 3.0.1, December 2002).

Bus structures 128 connect various components of system hardware 128. In one example, bus structures 128 may be one or more of several types of bus structure(s) including a memory bus, a peripheral bus or external bus, and/or a local bus using any variety of available bus architectures including, but not limited to, 11-bit bus, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Universal Serial Bus (USB), Advanced Graphics Port (AGP), Personal Computer Memory Card International Association bus (PCMCIA), and Small Computer Systems Interface (SCSI), a High Speed Synchronous Serial Interface (HSI), a Serial Low-power Inter-chip Media Bus (SLIMbus®), or the like.

Electronic device 100 may include an RF transceiver 130 to transceive RF signals, a Near Field Communication (NFC) radio 134, and a signal processing module 132 to process signals received by RF transceiver 130. RF transceiver may implement a local wireless connection via a protocol such as, e.g., Bluetooth or 802.11X. IEEE 802.11a, b, g or n-compliant interface (see, e.g., IEEE Standard for IT-Telecommunications and information exchange between systems LAN/MAN-Part II: Wireless LAN Medium Access Control (MAC) and Physical Layer (PHY) specifications Amendment 4: Further Higher Data Rate Extension in the 2.4 GHz Band, 802.11G-2003). Another example of a wireless interface would be a WCDMA, LTE, general packet radio service (GPRS) interface (see, e.g., Guidelines on GPRS Handset Requirements, Global System for Mobile Communications/GSM Association, Ver. 3.0.1, December 2002).

Electronic device 100 may further include one or more input/output interfaces such as, e.g., a keypad/touchpad 136 and a display 138. In some examples electronic device 100 may not have a keypad and use the touch panel for input.

Memory 140 may include an operating system 142 for managing operations of electronic device 100. In one example, operating system 142 includes a hardware interface module 154 that provides an interface to system hardware 120. In addition, operating system 140 may include a file system 150 that manages files used in the operation of electronic device 100 and a process control subsystem 152 that manages processes executing on electronic device 100.

Operating system 142 may include (or manage) one or more communication interfaces 146 that may operate in conjunction with system hardware 120 to transceive data packets and/or data streams from a remote source. Operating system 142 may further include a system call interface module 144 that provides an interface between the operating system 142 and one or more application modules resident in memory 130. Operating system 142 may be embodied as a UNIX operating system or any derivative thereof (e.g., Linux, Android, etc.) or as a Windows® brand operating system, or other operating systems.

In some examples an electronic device may include a controller 170, which may be separate from the primary execution environment. The separation may be physical in the sense that the controller may be implemented in controllers which are physically separate from the main processors. Alternatively, the separation may logical in the sense that the controller may be hosted on same chip or chipset that hosts the main processors.

By way of example, in some examples the controller 170 may be implemented as an independent integrated circuit located on the motherboard of the electronic device 100, e.g., as a dedicated processor block on the same SOC die. In other examples the controller 170 may be implemented on a portion of the processor(s) 122 that is segregated from the rest of the processor(s) using hardware enforced mechanisms

In the example depicted in FIG. 1 the controller 170 comprises a processor 172, a memory module 174, and an I/O interface 178. In some examples the memory module 174 may comprise a persistent flash memory module and the various functional modules may be implemented as logic instructions encoded in the persistent memory module, e.g., firmware or software. The I/O interface 178 may comprise a serial I/O module or a parallel I/O module. Because the controller 170 is separate from the main processor(s) 122 and operating system 142, the controller 170 may be made secure, i.e., inaccessible to hackers who typically mount software attacks from the host processor 122.

Electronic device 100 may comprise a configuration logic 176 which implements operations to determine a configuration for the electronic device and set one or more operational parameters of the electronic device in response to the configuration. The configuration logic 176 may be implemented in controller 170. Alternatively, or in addition, configuration logic 176 may reside in a memory 140 of electronic device 100 and may be executed by one or more main processor(s) 122 on electronic device 100.

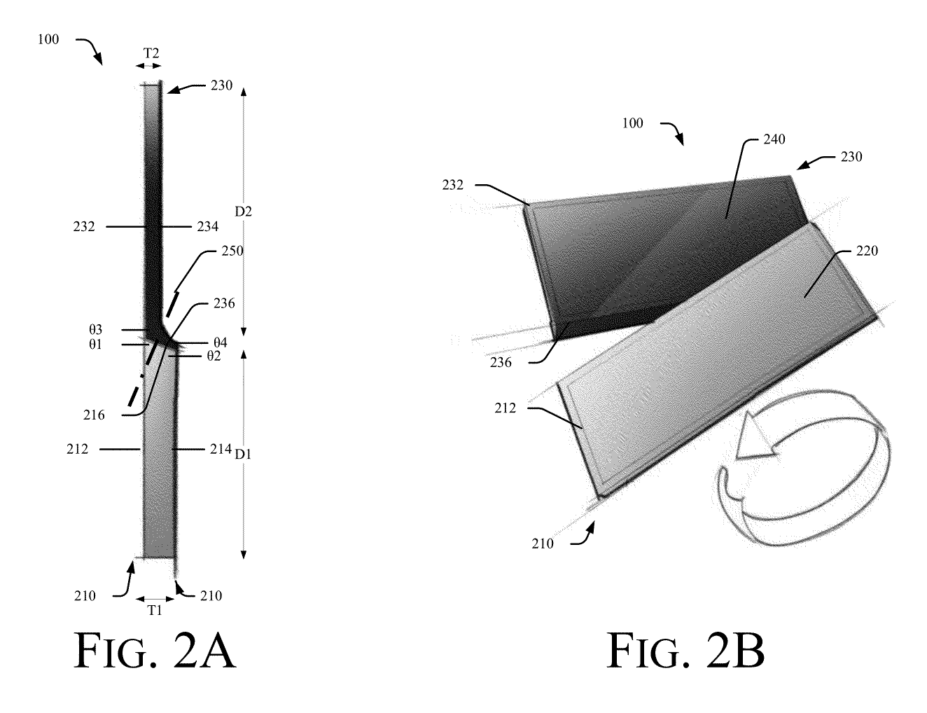

Referring to FIGS. 2A-2D, in some examples an electronic device 100, comprises a chassis which has a first housing 210 and a second housing 230 coupled to the first housing 210 such that the second housing 230 is rotatable about an axis 250 that extends diagonally through portions of the first housing 210 and the second housing 230.

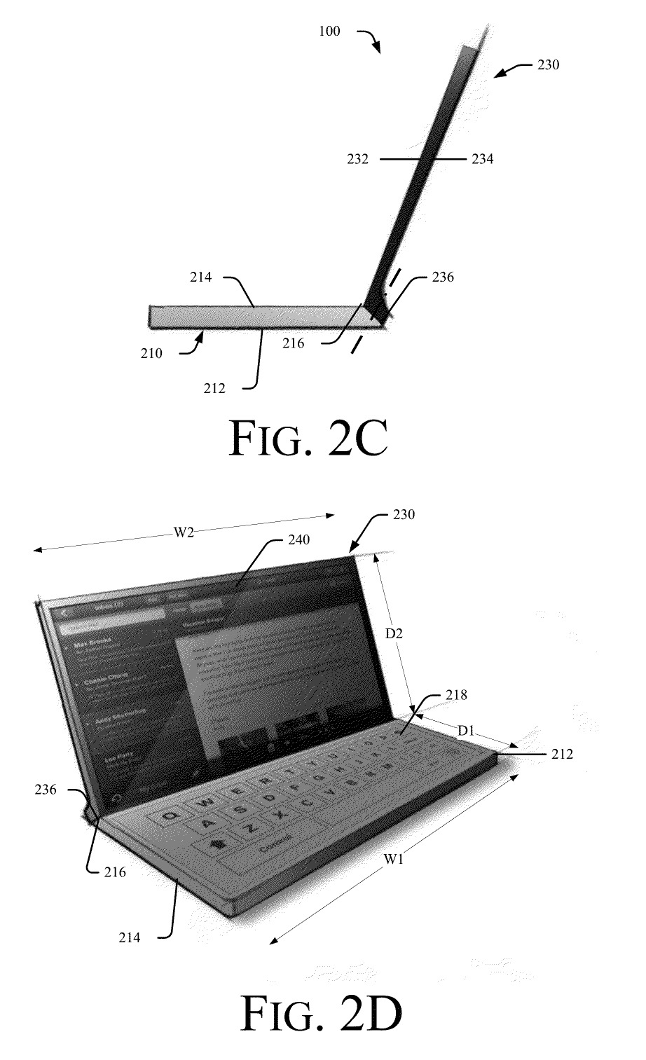

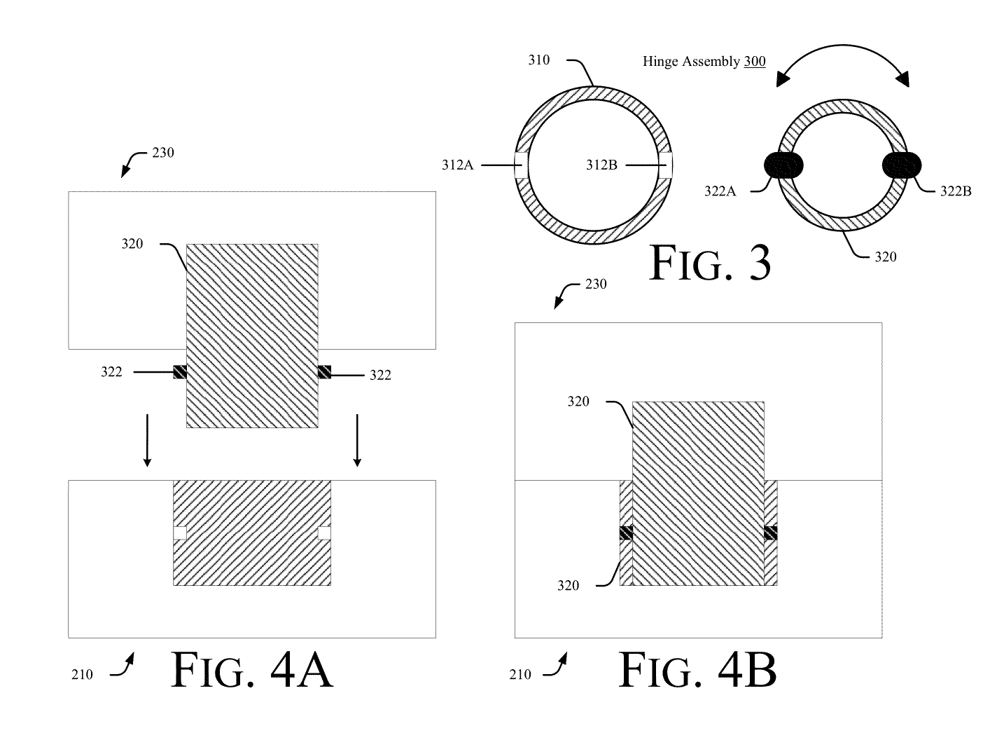

The first housing 210 comprises a first major surface 212 and a second major surface 214. The first major surface 212 of the first housing 210 comprises a first display 220 (FIG. 3), and the second major surface 214 of the first housing 210 comprises a keyboard 218 (FIGS. 4A, 4B).

Similarly, the second housing 230 comprises a first major surface 232 and a second major surface 234. The first major surface 232 of the second housing 230 comprises a second display 240 (FIG. 3).

As best illustrated in FIGS. 2 and 4A, the first housing 210 comprises a first side 216 which has a surface comprising portions which intersect the first major surface 212 at an angle, indicated by symbol θ1 in FIG. 2, that measures between about 60 degrees and about 80 degrees. Similarly, portions of the first side 216 surface intersect the second major surface 214 at an angle, indicated by symbol θ2 in FIG. 2, that measures between about 100 degrees and 120 degrees. In the example depicted in FIGS. 2-4B the first side 216 is substantially planar. However in alternate examples the first side 216 may be curved in either a convex or a concave fashion or may include multiple discrete planes.

The second housing 230 also comprises a first side 236 surface comprising portions which intersect the first major surface 232 at an angle, indicated by symbol θ3 in FIG. 2, that measures between about 60 degrees and about 80 degrees. Similarly, portions of the first side 236 surface intersect the second major surface at an angle, indicated by symbol θ4 in FIG. 2, that measures between about 100 degrees and about 120 degrees. In the example depicted in FIGS. 2-4B the first side 216 is substantially planar. However in alternate examples the first side 216 may be curved in either a convex or a concave fashion or may include multiple discrete planes.

As illustrated in FIGS. 2A-2D, the first housing 210 and the second housing may be rotatably coupled along the respective sides 216, 236 such that the second housing 230 is rotatable between a first position in which the electronic device 100 is in a tablet configuration (FIG. 1), and a second position in which the electronic device is in a notebook configuration (FIGS. 4A 4B). Thus, a user may readily convert the electronic device 100 from a tablet configuration as depicted in FIG. 2 to a notebook configuration as depicted in FIGS. 4A-4B by simply rotating the respective first housing 210 and/or second housing 230 about the axis 250.

The particular dimensions of electronic device 100 are not critical. In some examples the first housing 210 may have a width indicated by W1 that measures between about 8 inches and 16 inches, a thickness indicated by T1 that measures between about 0.25 inches and about 1.5 inches, and a depth indicated by D1 that measures between about 4 inches and about 8 inches. Similarly, the second housing 230 may have a width indicated by W2 that measures between 8 inches and 16 inches, a thickness indicated by T2 that measures between about 0.25 inches and about 1.5 inches, and a depth indicated by D2 that measures between about 4 inches and about 8 inches.

In some examples the first housing 210 and the second housing 230 are connected by a hinge assembly which enables rotational movement between the first housing 210 and the second housing 230 about axis 250. FIG. 3 is a schematic illustration of an exemplary hinge assembly in accordance with some examples. Referring to FIG. 3, in some examples a hinge assembly 300 comprises a first annular member 310 and a second annular member 320. The second annular member 320 is dimensioned to fit within the central region of the first annular member 310.

In some examples the first annular member 310 comprises slots 312A, 312B formed in the annular member 310. In the example depicted in FIG. 3 the slots 312A, 312B are formed opposite one another. Second annular member 320 comprises tabs 322A, 322B which are dimensioned to engage with slots 312A, 312B in first annular member when the second annular member 320 is disposed within the first annular member 310. In some examples the tabs 322A, 322B may be biased outwardly, e.g., by a spring or other bias mechanism, such that the tabs 322A, 322B engage the slots 312A, 312B. Thus, when the second annular member is inserted into the first annular member 310 and the tabs 322A, 322B are aligned with slots 312A, 312B the tabs 322A, 322B engage the slots 312A, 312B to securely position the second annular member 320 within the first annular member 310.

In some examples the tabs 322A, 322B may comprise rounded edges such that, under application of a rotational force to the second annular member 320, the tabs 322A, 322B are driven inwardly, which disengages the tabs 322A, 322B from the slots 312A, 312B. This enables the second annular member 320 to rotate within the first annular member 310, or to be completely removed from first annular member 310. The second annular member may be rotated 180 degrees, whereupon the tabs 322A, 322B will once again engage with the slots 312A, 312B to secure the second annular member 320 within the first annular member 310.

The particular dimensions of the first annular member 310 and the second annular member 320 are not critical. In some examples the first annular member 310 is dimensioned to fit within the first housing 210 and the second annular member 320 is dimensioned to fit within the second housing 230. The first annular member 310 and the second annular member 320 may be aligned along axis 250. Referring to FIGS. 4A-4B, the second housing 230 may be coupled to the first housing 210 by inserting the second annular member 320 into the first annular member 310 (FIG. 4B). Hinge assembly 300 then may be used to enable rotation of second housing 230 with respect to first housing 210.

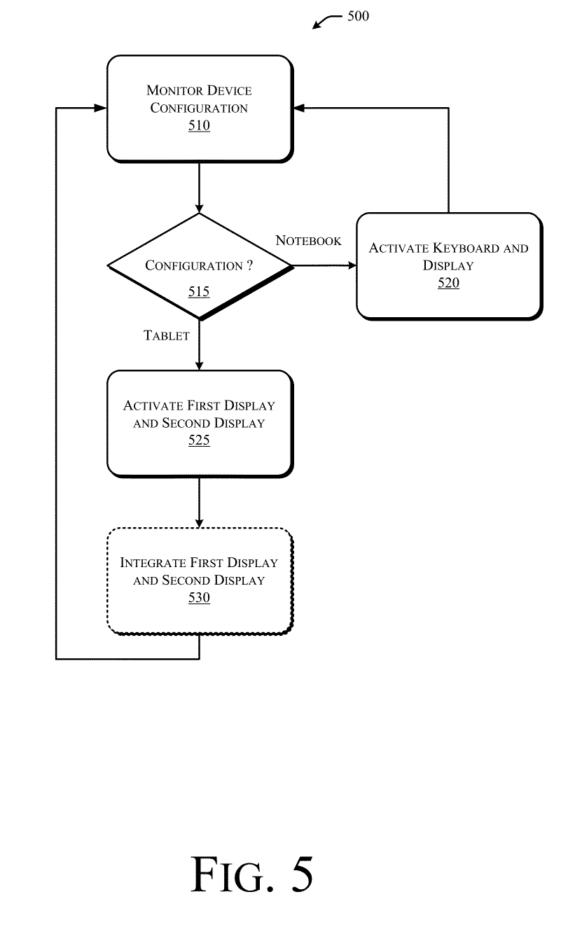

Referring to FIG. 1, in some examples the configuration logic 176 implements operations to monitor the configuration of the electronic device 100 and to set one or more operating parameters in response to the configuration. FIG. 5 is a flowchart illustrating operations implemented in a control logic of an electronic device in accordance with some examples. Referring to FIG. 5, at operation 510 the configuration logic 176 may monitor the configuration of electronic device 100.

If, at operation 515, the electronic device 100 is in a notebook configuration then control passes to operation 520 and the configuration logic 176 generates a signal which activates the keyboard 218 and the display 240 so that the electronic device 100 is configured in a notebook configuration.

By contrast, if at operation 515 the electronic device 100 is in a tablet configuration then control passes to operation 525 and the configuration logic 176 generates a signal which activates the display 220 and the display 240 so that the device 100 is configured in a tablet configuration.

In some examples the display 220 and display 240 may operate independently. In other examples the display 220 and the display 240 may be integrated (operation 530) when the electronic device 100 is in a tablet configuration such that the display 220 and the display 240 present as a single, integrated display. For example, configuration logic 176 may provide a signal to graphics processor(s) 124 to map graphics output to a display 240 when the electronic device 100 is in tablet configuration, and to map the graphics output to displays 220 and 240 as a single combined display when they electronic device 100 is in a tablet configuration.

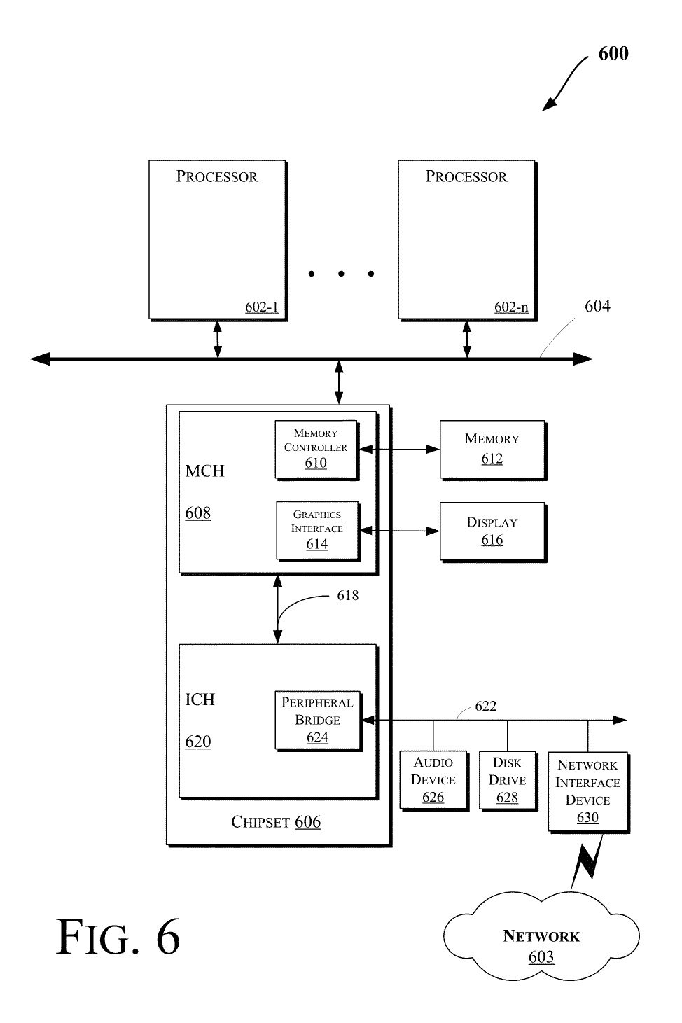

As described above, in some examples the electronic device 100 may be embodied as a computer system. FIG. 6 illustrates a block diagram of a computing system 600 in accordance with an example of the invention. The computing system 600 may include one or more central processing unit(s) (CPUs) 602 or processors that communicate via an interconnection network (or bus) 604. The processors 602 may include a general purpose processor, a network processor (that processes data communicated over a computer network 603), or other types of a processor (including a reduced instruction set computer (RISC) processor or a complex instruction set computer (CISC)). Moreover, the processors 602 may have a single or multiple core design. The processors 602 with a multiple core design may integrate different types of processor cores on the same integrated circuit (IC) die. Also, the processors 602 with a multiple core design may be implemented as symmetrical or asymmetrical multiprocessors. In an example, one or more of the processors 602 may be the same or similar to the processors 102 of FIG. 1.

A chipset 606 may also communicate with the interconnection network 604. The chipset 606 may include a memory control hub (MCH) 608. The MCH 608 may include a memory controller 610 that communicates with a memory 612 (which may be the same or similar to the memory 130 of FIG. 1). The memory 612 may store data, including sequences of instructions, that may be executed by the CPU 602, or any other device included in the computing system 600. In one example of the invention, the memory 612 may include one or more volatile storage (or memory) devices such as random access memory (RAM), dynamic RAM (DRAM), synchronous DRAM (SDRAM), static RAM (SRAM), or other types of storage devices. Nonvolatile memory may also be utilized such as a hard disk. Additional devices may communicate via the interconnection network 604, such as multiple CPUs and/or multiple system memories.

The MCH 608 may also include a graphics interface 614 that communicates with a display device 616. In one example of the invention, the graphics interface 614 may communicate with the display device 616 via an accelerated graphics port (AGP). In an example of the invention, the display 616 (such as a flat panel display) may communicate with the graphics interface 614 through, for example, a signal converter that translates a digital representation of an image stored in a storage device such as video memory or system memory into display signals that are interpreted and displayed by the display 616. The display signals produced by the display device may pass through various control devices before being interpreted by and subsequently displayed on the display 616.

A hub interface 618 may allow the MCH 608 and an input/output control hub (ICH) 620 to communicate. The ICH 620 may provide an interface to I/O device(s) that communicate with the computing system 600. The ICH 620 may communicate with a bus 622 through a peripheral bridge (or controller) 624, such as a peripheral component interconnect (PCI) bridge, a universal serial bus (USB) controller, or other types of peripheral bridges or controllers. The bridge 624 may provide a data path between the CPU 602 and peripheral devices. Other types of topologies may be utilized. Also, multiple buses may communicate with the ICH 620, e.g., through multiple bridges or controllers. Moreover, other peripherals in communication with the ICH 620 may include, in various examples of the invention, integrated drive electronics (IDE) or small computer system interface (SCSI) hard drive(s), USB port(s), a keyboard, a mouse, parallel port(s), serial port(s), floppy disk drive(s), digital output support (e.g., digital video interface (DVI)), or other devices.

The bus 622 may communicate with an audio device 626, one or more disk drive(s) 628, and a network interface device 630 (which is in communication with the computer network 603). Other devices may communicate via the bus 622. Also, various components (such as the network interface device 630) may communicate with the MCH 608 in some examples of the invention. In addition, the processor 602 and one or more other components discussed herein may be combined to form a single chip (e.g., to provide a System on Chip (SOC)). Furthermore, the graphics accelerator 616 may be included within the MCH 608 in other examples of the invention.

Furthermore, the computing system 600 may include volatile and/or nonvolatile memory (or storage). For example, nonvolatile memory may include one or more of the following: read-only memory (ROM), programmable ROM (PROM), erasable PROM (EPROM), electrically EPROM (EEPROM), a disk drive (e.g., 628), a floppy disk, a compact disk ROM (CD-ROM), a digital versatile disk (DVD), flash memory, a magneto-optical disk, or other types of nonvolatile machine-readable media that are capable of storing electronic data (e.g., including instructions).

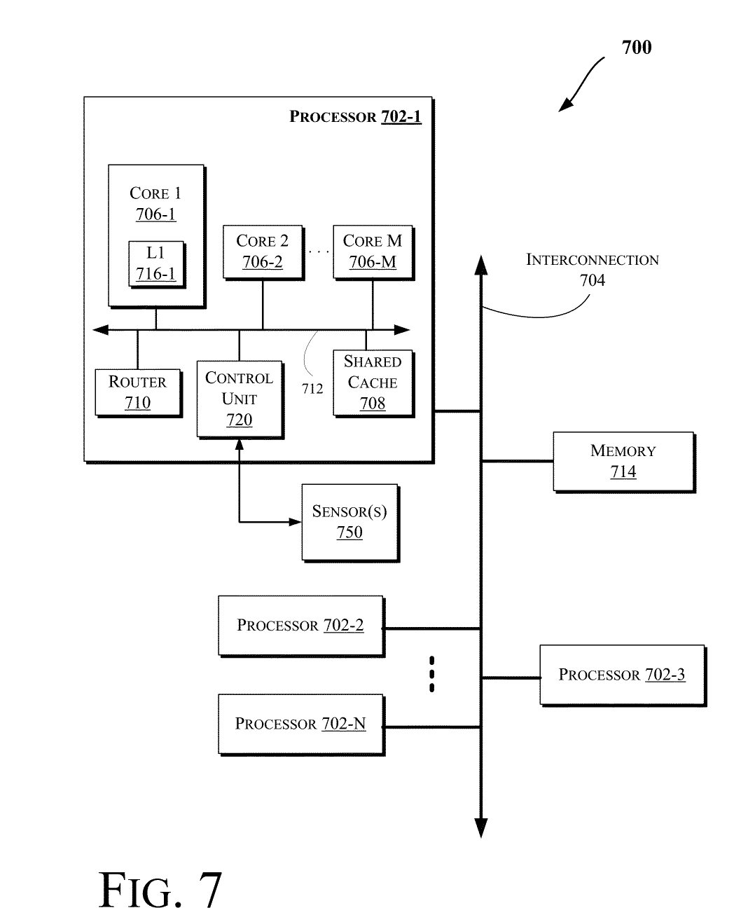

FIG. 7 illustrates a block diagram of a computing system 700, according to an example of the invention. The system 700 may include one or more processors 702-1 through 702-N (generally referred to herein as “processors 702” or “processor 702”). The processors 702 may communicate via an interconnection network or bus 704. Each processor may include various components some of which are only discussed with reference to processor 702-1 for clarity. Accordingly, each of the remaining processors 702-2 through 702-N may include the same or similar components discussed with reference to the processor 702-1.

In an example, the processor 702-1 may include one or more processor cores 706-1 through 706-M (referred to herein as “cores 706” or more generally as “core 706”), a shared cache 708, a router 710, and/or a processor control logic or unit 720. The processor cores 706 may be implemented on a single integrated circuit (IC) chip. Moreover, the chip may include one or more shared and/or private caches (such as cache 708), buses or interconnections (such as a bus or interconnection network 712), memory controllers, or other components.

In one example, the router 710 may be used to communicate between various components of the processor 702-1 and/or system 700. Moreover, the processor 702-1 may include more than one router 710. Furthermore, the multitude of routers 710 may be in communication to enable data routing between various components inside or outside of the processor 702-1.

The shared cache 708 may store data (e.g., including instructions) that are utilized by one or more components of the processor 702-1, such as the cores 706. For example, the shared cache 708 may locally cache data stored in a memory 714 for faster access by components of the processor 702. In an example, the cache 708 may include a mid-level cache (such as a level 2 (L2), a level 3 (L3), a level 4 (L4), or other levels of cache), a last level cache (LLC), and/or combinations thereof. Moreover, various components of the processor 702-1 may communicate with the shared cache 708 directly, through a bus (e.g., the bus 712), and/or a memory controller or hub. As shown in FIG. 7, in some examples, one or more of the cores 706 may include a level 1 (L1) cache 716-1 (generally referred to herein as “L1 cache 716”). In one example, the controller 720 may include logic to implement the operations described above with reference to FIG. 3.

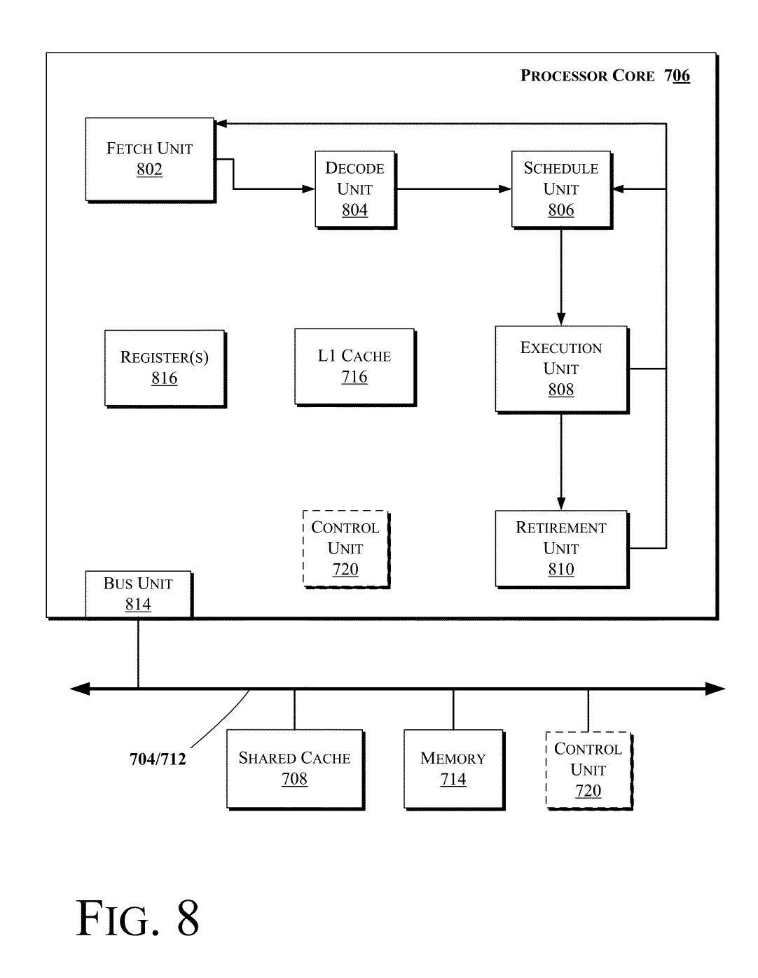

FIG. 8 illustrates a block diagram of portions of a processor core 706 and other components of a computing system, according to an example of the invention. In one example, the arrows shown in FIG. 8 illustrate the flow direction of instructions through the core 706. One or more processor cores (such as the processor core 706) may be implemented on a single integrated circuit chip (or die) such as discussed with reference to FIG. 7. Moreover, the chip may include one or more shared and/or private caches (e.g., cache 708 of FIG. 7), interconnections (e.g., interconnections 704 and/or 112 of FIG. 7), control units, memory controllers, or other components.

As illustrated in FIG. 8, the processor core 706 may include a fetch unit 802 to fetch instructions (including instructions with conditional branches) for execution by the core 706. The instructions may be fetched from any storage devices such as the memory 714. The core 706 may also include a decode unit 804 to decode the fetched instruction. For instance, the decode unit 804 may decode the fetched instruction into a plurality of uops (micro-operations).

Additionally, the core 706 may include a schedule unit 806. The schedule unit 806 may perform various operations associated with storing decoded instructions (e.g., received from the decode unit 804) until the instructions are ready for dispatch, e.g., until all source values of a decoded instruction become available. In one example, the schedule unit 806 may schedule and/or issue (or dispatch) decoded instructions to an execution unit 808 for execution. The execution unit 808 may execute the dispatched instructions after they are decoded (e.g., by the decode unit 804) and dispatched (e.g., by the schedule unit 806). In an example, the execution unit 808 may include more than one execution unit. The execution unit 808 may also perform various arithmetic operations such as addition, subtraction, multiplication, and/or division, and may include one or more an arithmetic logic units (ALUs). In an example, a co-processor (not shown) may perform various arithmetic operations in conjunction with the execution unit 808.

Further, the execution unit 808 may execute instructions out-of-order. Hence, the processor core 706 may be an out-of-order processor core in one example. The core 706 may also include a retirement unit 810. The retirement unit 810 may retire executed instructions after they are committed. In an example, retirement of the executed instructions may result in processor state being committed from the execution of the instructions, physical registers used by the instructions being de-allocated, etc.

The core 706 may also include a bus unit 714 to enable communication between components of the processor core 706 and other components (such as the components discussed with reference to FIG. 8) via one or more buses (e.g., buses 804 and/or 812). The core 706 may also include one or more registers 816 to store data accessed by various components of the core 706 (such as values related to power consumption state settings).

Furthermore, even though FIG. 7 illustrates the control unit 720 to be coupled to the core 706 via interconnect 812, in various examples the control unit 720 may be located elsewhere such as inside the core 706, coupled to the core via bus 704, etc.

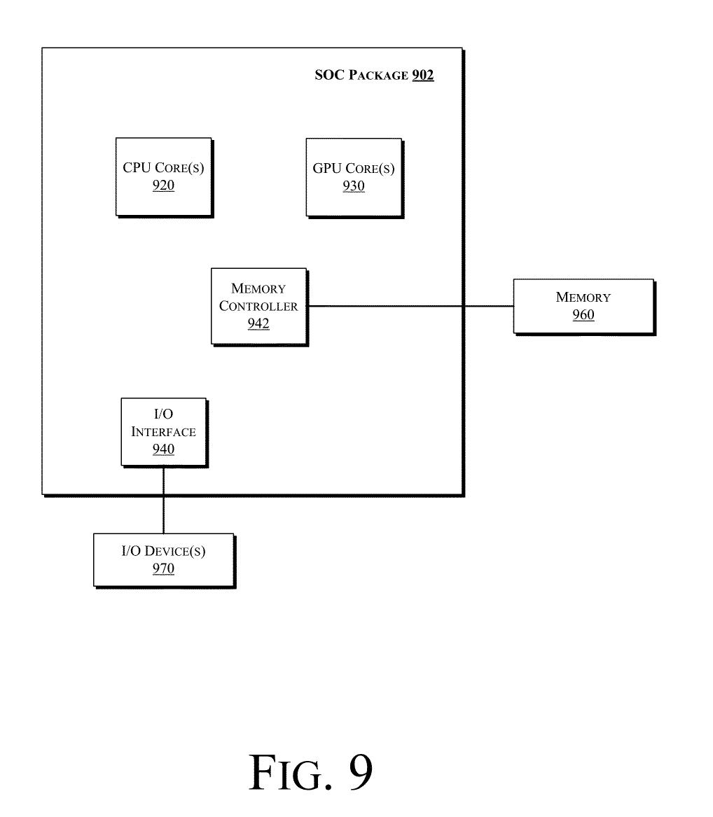

In some examples, one or more of the components discussed herein can be embodied as a System On Chip (SOC) device. FIG. 9 illustrates a block diagram of an SOC package in accordance with an example. As illustrated in FIG. 9, SOC 902 includes one or more Central Processing Unit (CPU) cores 920, one or more Graphics Processor Unit (GPU) cores 930, an Input/Output (I/O) interface 940, and a memory controller 942. Various components of the SOC package 902 may be coupled to an interconnect or bus such as discussed herein with reference to the other figures. Also, the SOC package 902 may include more or less components, such as those discussed herein with reference to the other figures. Further, each component of the SOC package 902 may include one or more other components, e.g., as discussed with reference to the other figures herein. In one example, SOC package 902 (and its components) is provided on one or more Integrated Circuit (IC) die, e.g., which are packaged into a single semiconductor device.

As illustrated in FIG. 9, SOC package 902 is coupled to a memory 960 (which may be similar to or the same as memory discussed herein with reference to the other figures) via the memory controller 942. In an example, the memory 960 (or a portion of it) can be integrated on the SOC package 902.

The I/O interface 940 may be coupled to one or more I/O devices 970, e.g., via an interconnect and/or bus such as discussed herein with reference to other figures. I/O device(s) 970 may include one or more of a keyboard, a mouse, a touchpad, a display, an image/video capture device (such as a camera or camcorder/video recorder), a touch screen, a speaker, or the like.

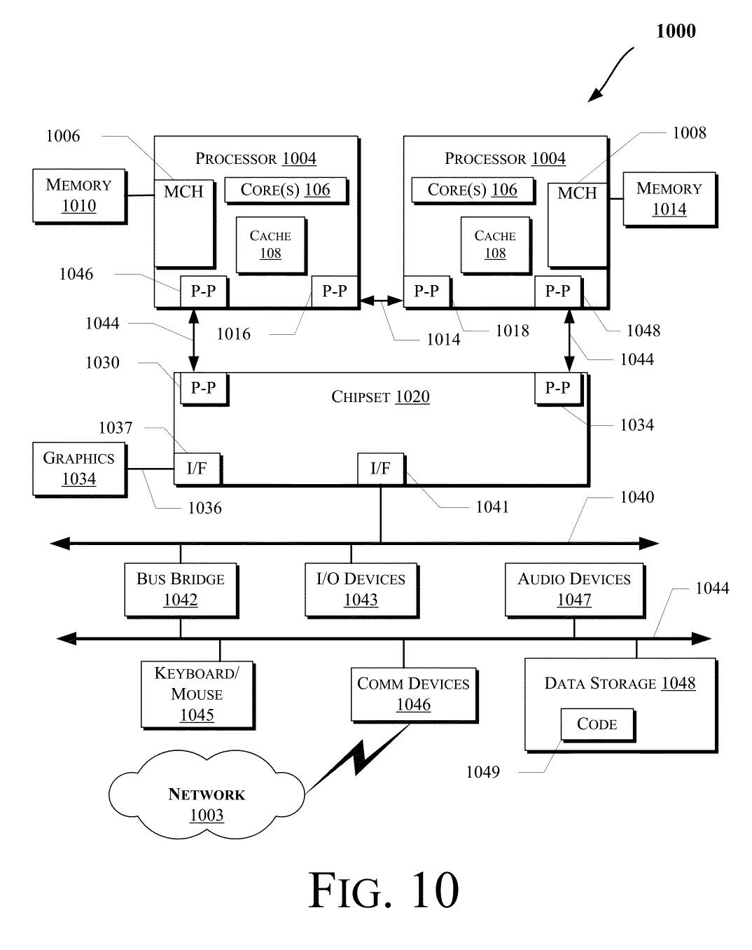

FIG. 10 illustrates a computing system 1000 that is arranged in a point-to-point (PtP) configuration, according to an example of the invention. In particular, FIG. 10 shows a system where processors, memory, and input/output devices are interconnected by a number of point-to-point interfaces.

As illustrated in FIG. 10, the system 1000 may include several processors, of which only two, processors 1002 and 1004 are shown for clarity. The processors 1002 and 1004 may each include a local memory controller hub (MCH) 1006 and 1008 to enable communication with memories 1010 and 1012. MCH 1006 and 1008 may include the memory controller 120 and/or logic 125 of FIG. 1 in some examples.

In an example, the processors 1002 and 1004 may be one of the processors 702 discussed with reference to FIG. 7. The processors 1002 and 1004 may exchange data via a point-to-point (PtP) interface 1014 using PtP interface circuits 1016 and 1018, respectively. Also, the processors 1002 and 1004 may each exchange data with a chipset 1020 via individual PtP interfaces 1022 and 1024 using point-to-point interface circuits 1026, 1028, 1030, and 1032. The chipset 1020 may further exchange data with a high-performance graphics circuit 1034 via a high-performance graphics interface 1036, e.g., using a PtP interface circuit 1037.

As shown in FIG. 10, one or more of the cores 106 and/or cache 108 of FIG. 1 may be located within the processors 1004. Other examples of the invention, however, may exist in other circuits, logic units, or devices within the system 1000 of FIG. 10. Furthermore, other examples of the invention may be distributed throughout several circuits, logic units, or devices illustrated in FIG. 10.

The chipset 1020 may communicate with a bus 1040 using a PtP interface circuit 1041. The bus 1040 may have one or more devices that communicate with it, such as a bus bridge 1042 and I/O devices 1043. Via a bus 1044, the bus bridge 1043 may communicate with other devices such as a keyboard/mouse 1045, communication devices 1046 (such as modems, network interface devices, or other communication devices that may communicate with the computer network 1003), audio I/O device, and/or a data storage device 1048. The data storage device 1048 (which may be a hard disk drive or a NAND flash based solid state drive) may store code 1049 that may be executed by the processors 1004.

The following pertain to further examples.

Example 1 is a chassis for an electronic device, comprising a first housing and a second housing, the second housing coupled to the first housing such that the second housing is rotatable about an axis that extends diagonally through portions of the first housing and the second housing.

In Example 2, the subject matter of Example 1 can optionally include an arrangement in which the first housing comprises a first major surface and a second major surface and a first side surface comprising portions which intersect the first major surface at an angle that measures between about 60 degrees and about 80 degrees.

In Example 3, the subject matter of any one of Examples 1-2 can optionally include an arrangement in which portions of the first side surface intersect the second major surface at an angle that measures between about 100 degrees and about 120 degrees.

In Example 4, the subject matter of any one of Examples 1-3 can optionally include an arrangement in which the first major surface of the first housing comprises a first display and the second major surface of the first housing comprises a keyboard.

In Example 5, the subject matter of any one of Examples 1-4 can be arranged such that the second housing comprises a first major surface and a second major surface and a first side surface comprising portions which intersect the first major surface at an angle that measures between about 60 degrees and about 80 degrees.

In Example 6, the subject matter of any one of Examples 1-5 can optionally include an arrangement in which portions of the first side surface intersect the second major surface at an angle that measures between about 100 degrees and about 120 degrees.

In Example 7, the subject matter of any one of Examples 1-6 can be arranged such that the first major surface of the second housing comprises a second display.

In Example 8, the subject matter of any one of Examples 1-7 can optionally include an arrangement in which the second housing is rotatable between a first position in which the chassis is in a tablet configuration and a second position in which the chassis is in a notebook configuration.

In Example 9, the subject matter of any one of Examples 1-8 can optionally include an arrangement in which the first housing is coupled to the second housing by a hinge assembly that allows for rotational movement between the first housing and the second housing.

In Example 10, the subject matter of any one of Examples 1-9 can optionally include an arrangement in which the hinge assembly comprises a first annular member comprising opposing slots and a second annular member comprising opposing tabs positioned and dimensioned to engage with the opposing slots

Example 11 is an electronic device, comprising a first housing and a second housing, the second housing coupled to the first housing such that the second housing is rotatable about an axis that extends diagonally through portions of the first housing and the second housing and logic, at least partially including hardware logic, to detect when a chassis for an electronic device is in a first position in which the electronic device is in a tablet configuration and in response to detecting that the electronic device is in a first configuration, to activate a first display and a second display.

In Example 12, the subject matter of Example 11 can optionally include an arrangement in which the first housing comprises a first major surface and a second major surface and a first side surface comprising portions which intersect the first major surface at an angle that measures between about 60 degrees and about 80 degrees.

In Example 13, the subject matter of any one of Examples 11-12 can optionally include an arrangement in which portions of the first side surface intersect the second major surface at an angle that measures between about 100 degrees and about 120 degrees.

In Example 14, the subject matter of any one of Examples 11-13 can optionally include an arrangement in which the first major surface of the first housing comprises a first display and the second major surface of the first housing comprises a keyboard.

In Example 15, the subject matter of any one of Examples 11-14 can be arranged such that the second housing comprises a first major surface and a second major surface and a first side surface comprising portions which intersect the first major surface at an angle that measures between about 60 degrees and about 80 degrees.

In Example 16, the subject matter of any one of Examples 11-15 can optionally include an arrangement in which portions of the first side surface intersect the second major surface at an angle that measures between about 100 degrees and about 120 degrees.

In Example 17, the subject matter of any one of Examples 11-16 can be arranged such that the first major surface of the second housing comprises a second display.

In Example 18, the subject matter of any one of Examples 11-17 can optionally include an arrangement in which the second housing is rotatable between a first position in which the chassis is in a tablet configuration and a second position in which the chassis is in a notebook configuration.

In Example 19, the subject matter of any one of Examples 11-18 can optionally include logic to activate the first display and the second display when the electronic device is in a tablet configuration.

In Example 20, the subject matter of any one of Examples 11-19 can optionally include logic, at least partially including hardware logic, to integrate the first display and the second display when the electronic device is in a tablet configuration.

In Example 21, the subject matter of any one of Examples 11-20 can optionally include logic, at least partially including hardware logic, to activate the keyboard and the second display when the electronic device is in a notebook configuration.

In Example 22, the subject matter of any one of Examples 11-21 can optionally include logic, at least partially including hardware logic, to deactivate the keyboard and the second display when the electronic device is in a tablet configuration.

In Example 23, the subject matter of any one of Examples 11-22 can optionally include an arrangement in which the first housing is coupled to the second housing by a hinge assembly that allows for rotational movement between the first housing and the second housing.

In Example 24, the subject matter of any one of Examples 11-23 can optionally include an arrangement in which the hinge assembly comprises a first annular member comprising opposing slots and a second annular member comprising opposing tabs positioned and dimensioned to engage with the opposing slots.

Example 25 is a controller comprising logic, at least partially including hardware logic, to detect when a chassis for an electronic device is in a first position in which the electronic device is in a tablet configuration and in response to detecting that the electronic device is in a first configuration, to activate a first display and a second display.

In Example 26, the subject matter of Example 25 can optionally include logic, at least partially including hardware logic, to integrate the first display and the second display when the electronic device is in a tablet configuration.

In Example 27, the subject matter of any one of Examples 25-26 can optionally include logic, at least partially including hardware logic, to detect when a chassis for an electronic device is in a second position in which the electronic device is in a notebook configuration and activate the keyboard and the second display when the electronic device is in a notebook configuration

In Example 27, the subject matter of any one of Examples 25-26 can optionally include logic, at least partially including hardware logic, to detect when a chassis for an electronic device is in a second position in which the electronic device is in a notebook configuration and deactivate the keyboard and the second display when the electronic device is in a tablet configuration.

The terms “logic instructions” as referred to herein relates to expressions which may be understood by one or more machines for performing one or more logical operations. For example, logic instructions may comprise instructions which are interpretable by a processor compiler for executing one or more operations on one or more data objects. However, this is merely an example of machine-readable instructions and examples are not limited in this respect.

The terms “computer readable medium” as referred to herein relates to media capable of maintaining expressions which are perceivable by one or more machines. For example, a computer readable medium may comprise one or more storage devices for storing computer readable instructions or data. Such storage devices may comprise storage media such as, for example, optical, magnetic or semiconductor storage media. However, this is merely an example of a computer readable medium and examples are not limited in this respect.

The term “logic” as referred to herein relates to structure for performing one or more logical operations. For example, logic may comprise circuitry which provides one or more output signals based upon one or more input signals. Such circuitry may comprise a finite state machine which receives a digital input and provides a digital output, or circuitry which provides one or more analog output signals in response to one or more analog input signals. Such circuitry may be provided in an application specific integrated circuit (ASIC) or field programmable gate array (FPGA). Also, logic may comprise machine-readable instructions stored in a memory in combination with processing circuitry to execute such machine-readable instructions. However, these are merely examples of structures which may provide logic and examples are not limited in this respect.

Some of the methods described herein may be embodied as logic instructions on a computer-readable medium. When executed on a processor, the logic instructions cause a processor to be programmed as a special-purpose machine that implements the described methods. The processor, when configured by the logic instructions to execute the methods described herein, constitutes structure for performing the described methods. Alternatively, the methods described herein may be reduced to logic on, e.g., a field programmable gate array (FPGA), an application specific integrated circuit (ASIC) or the like.

In the description and claims, the terms coupled and connected, along with their derivatives, may be used. In particular examples, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one example” or “some examples” means that a particular feature, structure, or characteristic described in connection with the example is included in at least an implementation. The appearances of the phrase “in one example” in various places in the specification may or may not be all referring to the same example.

Although examples have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. A chassis for an electronic device, comprising:
a first housing and a second housing, the second housing coupled to the first housing such that the second housing is rotatable about an axis that extends diagonally through portions of the first housing and the second housing.

2. The chassis of claim 1, wherein the first housing comprises:
a first major surface and a second major surface; and
a first side surface comprising portions which intersect the first major surface at an angle that measures between about 60 degrees and about 80 degrees.

3. The chassis of claim 2, wherein portions of the first side surface intersect the second major surface at an angle that measures between about 100 degrees and about 120 degrees.

4. The chassis of claim 1, wherein:
the first major surface of the first housing comprises a first display; and
the second major surface of the first housing comprises a keyboard.

5. The chassis of claim 1, wherein the second housing comprises:
a first major surface and a second major surface; and
a first side surface comprising portions which intersect the first major surface at an angle that measures between about 60 degrees and about 80 degrees.

6. The chassis of claim 5, wherein portions of the first side surface intersect the second major surface at an angle that measures between about 100 degrees and about 120 degrees.

7. The chassis of claim 1, wherein:
the first major surface of the second housing comprises a second display.

8. The chassis of claim 1, wherein the second housing is rotatable between:
a first position in which the chassis is in a tablet configuration; and
a second position in which the chassis is in a notebook configuration.

9. The chassis of claim 1, wherein the first housing is coupled to the second housing by a hinge assembly that allows for rotational movement between the first housing and the second housing.

10. The chassis of claim 9, wherein the hinge assembly comprises:
a first annular member comprising opposing slots; and
a second annular member comprising opposing tabs positioned and dimensioned to engage with the opposing slots.

11. An electronic device, comprising:
a first housing and a second housing, the second housing coupled to the first housing such that the second housing is rotatable about an axis that extends diagonally through portions of the first housing and the second housing; and
logic, at least partially including hardware logic, to:
detect when a chassis for an electronic device is in a first position in which the electronic device is in a tablet configuration; and
in response to detecting that the electronic device is in a first configuration, to activate a first display and a second display.

12. The electronic device of claim 11, wherein the first housing comprises:
a first major surface and a second major surface; and
a first side surface comprising portions which intersect the first major surface at an angle that measures between about 60 degrees and about 80 degrees.

13. The electronic device of claim 12, wherein portions of the first side surface intersect the second major surface at an angle that measures between about 100 degrees and about 120 degrees.

14. The electronic device of claim 11, wherein:
the first major surface of the first housing comprises a first display; and
the second major surface of the first housing comprises a keyboard.

15. The electronic device of claim 11, wherein the second housing comprises:
a first major surface and a second major surface; and
a first side surface comprising portions which intersect the first major surface at an angle that measures between about 60 degrees and about 80 degrees.

16. The electronic device of claim 14, wherein portions of the first side surface intersect the second major surface at an angle that measures between about 100 degrees and about 120 degrees.

17. The electronic device of claim 11, wherein:
the first major surface of the second housing comprises a second display.

18. The electronic device of claim 11, wherein the second housing is rotatable between:
a first position in which the electronic device is in a tablet configuration; and
a second position in which the electronic device is in a notebook configuration.

19. The electronic device of claim 18, further comprising logic to:
activate the first display and the second display when the electronic device is in a tablet configuration.

20. The electronic device of claim 18, further comprising logic, at least partially including hardware logic, to:
integrate the first display and the second display when the electronic device is in a tablet configuration.

21. The electronic device of claim 18, further comprising logic, at least partially including hardware logic, to:
activate the keyboard and the second display when the electronic device is in a notebook configuration.

22. The electronic device of claim 18, further comprising logic, at least partially including hardware logic, to:
deactivate the keyboard and the second display when the electronic device is in a tablet configuration.

23. The electronic device of claim 11, wherein the first housing is coupled to the second housing by a hinge assembly that allows for rotational movement between the first housing and the second housing.

24. The electronic device of claim 23, wherein the hinge assembly comprises:
a first annular member comprising opposing slots; and
a second annular member comprising opposing tabs positioned and dimensioned to engage with the opposing slots.

25. A controller comprising logic, at least partially including hardware logic, to:
detect when a chassis for an electronic device is in a first position in which the electronic device is in a tablet configuration; and
in response to detecting that the electronic device is in a first configuration, to activate a first display and a second display.
